(19) United States
(12) Patent Application Publication
(10) Pub. No.: US 2006/0060937 A1
(43) Pub. Date: Mar. 23, 2006

(54) Embedded passive component

(75) Inventors: Eng Han Matthew Lim, Singapore (SG); Chuan Wei Ivan Wong, Singapore (SG); Kee Kwang Lau, Singapore (SG); Kim Hwee Tan, Singapore (SG); Yin Yen Bong, Malaysia (MY)

Correspondence Address: CONLEY ROSE, P.C., P. O. BOX 3267, HOUSTON, TX, 77253-3267, US

(73) Assignee: Advanpack Solutions Pte Ltd, Singapore (SG)

(21) Appl. No.: 10/947,910

(22) Filed: Sep. 23, 2004

(51) Int. Cl. H01L 29/00

(52) U.S. Cl. 257/516

(57) ABSTRACT

As the functionality, speed and portability of consumer electronics increases, so does the need for more circuitry to be packed into smaller spaces. All this leads to the fact that the size of a device is now becoming more often a function of the circuit board or module size than anything else. In order to achieve size reduction of multi-featured products, passive components on the surface of the circuit need to be eliminated by burying them within the inner layers of the printed wiring board. Embedded passives are passive components placed between the interconnecting substrates of a printed wiring board. Implementation of embedded passives reduces space requirements and enables more silicon devices to be placed on the same sized substrate, thereby allowing functional potential of small electronic devices to increase. However, additional steps are conventionally required for embedding passive components within the interconnect layer between substrates. An embodiment of the invention discloses an embedded passive component comprising electrically conductive pillars formed on a substrate. One portion of the pillars functions as a passive structure and another portion of the pillars functions as inter-displacement means. As only pillars are used, steps for forming the embedded passive component are simplified and quantitatively reduced.

### FIELD OF INVENTION

The present invention relates generally to an embedded passive component. In particular, the invention relates to passive components embedded within an interconnect layer.

### BACKGROUND

As the functionality, speed and portability of consumer electronics increases, so does the need for more circuitry to be packed into smaller spaces. The latest cell phone not only communicating voice but also interfacing with a computer to provide real-time information, and handheld devices being provided with wireless communication interfaces are examples of constant functionality increment that causes the quantity requirement of integrated circuits (IC) and passive components to increase dramatically. Furthermore, as operating speed increases, capacitors are required to be closer to the I.C. to avoid parasitic inductance effects. All this leads to the fact that the size of a device is now becoming more often a function of the circuit board or module size than anything else. In order to achieve size reduction of multi-featured products, passive components on the surface of the circuit need to be eliminated by burying them within the inner layers of the printed wiring board.

Embedded passives are passive components placed between the interconnecting substrates of a printed wiring board. With embedded passives, components such as resistors, capacitors and inductors are embedded into the body of a printed wiring board.

Implementation of embedded passives reduces space requirements and enables more silicon devices to be placed on the same sized substrate, thereby allowing functional potential of small electronic devices to increase. There are many other potential advantages to embedding passives in printed wiring boards for many types of applications. Capacitors could be placed directly underneath the active component they support, thereby reducing the number of layers and interconnecting vias. This would simplify board construction thereby, reducing costs and lower parasitic inductance and cross talk.

A capacitor dielectric placed between the power and ground plane would lower noise and provide blocking capacitors for filtering applications. Resistors are embeddable, providing similar advantages. Additional advantages gained would include a large reduction in the number of solder joints leading to improved reliability.

However, additional steps are conventionally required for embedding passive components within the interconnect layer between substrates. The orientations of passive components, for example a capacitor, between interconnects increases the thickness of the dielectric insulating material between the interconnect layers and presents a bulge in the dielectric insulating material deposited on top of the capacitor. Therefore, extra effort time and processing steps are required for performing planarisation steps to achieve a substantial planarity.

U.S. Pat. No. 6,417,556 (Long) describes an integrated circuit wherein a de-coupling capacitor is formed within an interconnect layer. U.S. Pat. No. 6,504,202 BI (Allman) describes an integrated circuit having a metal-insulator-metal (MIM) capacitor embedded within an interconnect layer. However, each of Long and Allman presents a solution wherein the interconnect layer(s) are stratified over the passive component (the capacitor), thereby requiring complicated interconnect layer forming steps. Furthermore, the interconnect layer has to be formed not only to accommodate the embedded passive but also to facilitate interfacing with a substrate.

Hence, this clearly affirms a need for an improved embedded passive component.

### SUMMARY

In accordance with a first aspect of the invention, there is disclosed an embedded passive component comprising:
a substrate comprising a pattern formed thereon, the pattern being electrically conductive;
a first plurality of pillars extending from the substrate, each of the first plurality of pillars having a free end and at least one of the first plurality of pillars for coupling to a carrier having a circuitry; and
a passive structure for functioning as an electrically passive element, the passive structure comprising:
a second plurality of pillars extending from the substrate,
wherein the pattern on the substrate electrically communicates at least one of the first plurality of pillars with at least one of the second plurality of pillars,
whereby when at least one of the first plurality of pillars is coupled to the carrier, the at least one of the first plurality of pillars structurally inter-couples and spatially inter-displaces the substrate and the carrier to thereby electrically communicate the passive structure formed by the second plurality of pillars with the circuitry formed on the carrier.

In accordance with a second aspect of the invention, there is disclosed an embedded passive component comprising:
a substrate comprising a pattern formed thereon, the pattern being electrically conductive and the substrate being planar;
a first plurality of pillars extending from the substrate, each of the first plurality of pillars having a free end and at least one of the first plurality of pillars for coupling to a carrier having a circuitry, each of the first plurality of pillars being substantially perpendicular to the substrate; and
a passive structure for functioning as an electrically passive element, the passive structure comprising:
a second plurality of pillars extending from the substrate, each of the second plurality of pillars being substantially perpendicular to the substrate, each adjacent pair of a portion of the second plurality of pillars being inter-abutting,
wherein the pattern on the substrate electrically communicates at least one of the first plurality of pillars with at least one of the second plurality of pillars,
whereby when at least one of the first plurality of pillars is coupled to the carrier, the at least one of the first plurality of pillars structurally inter-couples and spatially inter-displaces the substrate and the carrier to thereby electrically communicate the passive structure formed by the second plurality of pillars with the circuitry formed on the carrier.

In accordance with a third aspect of the invention, there is disclosed an embedded passive component comprising:
a substrate comprising a pattern formed thereon, the pattern being electrically conductive and the substrate being planar; and
a passive structure for functioning as an electrically passive element, the passive structure comprising:
a plurality of pillars extending from the substrate, each of the plurality of pillars being substantially perpendicular to the substrate, each adjacent pair of a portion of the second plurality of pillars being inter-abutting,
wherein when the pattern is electrically connected to a circuitry, the pattern on the substrate electrically communicates at least one of the plurality of pillars with the circuitry.

### BRIEF DESCRIPTION OF THE DRAWINGS

Embodiments of the invention are described hereinafter with reference to the following drawings, in which:

FIG. 1 shows a partial front sectional elevation of an embedded passive component according to a first embodiment of the invention comprising a passive structure and first pillars having a solder bump formed on a free-end of each thereof, the embedded passive component being shown mounted onto a carrier;

FIG. 2 shows a partial front sectional elevation of the embedded passive component of FIG. 1 with each of the first pillars comprising a base portion and a solder portion;

FIG. 3 shows a partial front sectional view of the embedded passive component of FIG. 2 with the passive structure encapsulated in an insulating layer;

FIG. 4 shows a plan view of view ‘A’ of the embedded passive component of FIG. 2 with the passive structure forming a resistor;

FIG. 5 shows a plan view of the embedded passive component of FIG. 1 according to a second embodiment of the invention with the passive structure forming an inductor;

FIG. 6 shows a partial plan sectional view of the embedded passive component of FIG. 1 according to a third embodiment of the invention with the passive structure forming a capacitor;

FIG. 7 shows a partial plan sectional view of the embedded passive component of FIG. 1 according to a fourth embodiment of the invention with the passive structure forming a capacitor;

FIG. 8 shows a partial plan sectional view of the passive structure of the embedded passive component of FIG. 1; and

FIG. 9 shows a plan view of the embedded passive component of FIG. 1 according to a fifth embodiment of the invention.

### DETAILED DESCRIPTION

An embedded passive component is described hereinafter for addressing the foregoing problems.

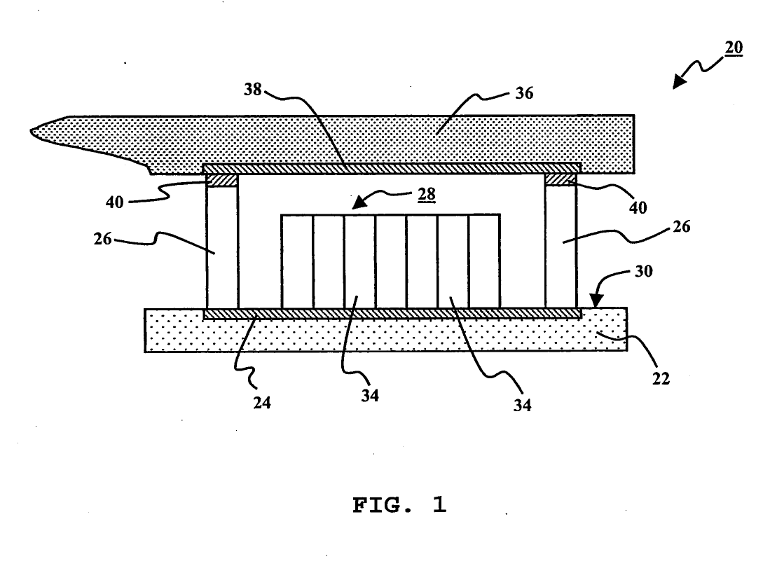

A first embodiment of the invention, an embedded passive component 20 is described with reference to FIG. 1, which shows a partial front sectional elevation of the embedded passive component.

As shown in FIG. 1, the embedded passive component 20 comprises a substrate 22 with a pattern 24 formed thereon. The pattern 22 is electrically conductive for the carriage of signal therealong. The embedded passive device 20 further comprises first pillars 26 and a passive structure 28 formed on the substrate 22. The substrate 22 is substantially planar and comprises a mounting face 30. The pattern 22 preferably constitutes a portion of the mounting face 30.

Each of the first pillars 26 extends from the mounting face 30 of the substrate 22 and terminates at a free-end 32. A portion of the pattern 22 interfaces each of the first pillars 26 and the substrate 22 for forming electrical communication with the first pillars 26. Alternatively, only a portion of the first pillars 26 is in electrical communication with the pattern 22.

The passive structure 28 is preferably for functioning as an electrically passive element and comprises second pillars 34 extending from the mounting face 30 of the substrate 22. The first pillars 26 and the second pillars 34 are formed substantially perpendicular to the substrate 22. A portion of the pattern 22 also interfaces a portion of the first pillars 26 and the substrate 22 for forming electrical communication between a portion of the first pillars 26 and a portion of the second pillars 24.

The first pillars 26 and the second pillars 34 form free-standing structures on the substrate 22. However, at least a portion of the first group 26 of pillars is for coupling to a carrier 36 having a circuitry 38. When at least one of the first pillars 26 is coupled to the carrier 36, the at least one of the first pillars 26 structurally inter-couples and spatially inter-displaces the substrate 22 and the carrier 36 to thereby electrically communicate the passive structure formed 28 by the second pillars 34 with the circuitry 38 formed on the carrier 36.

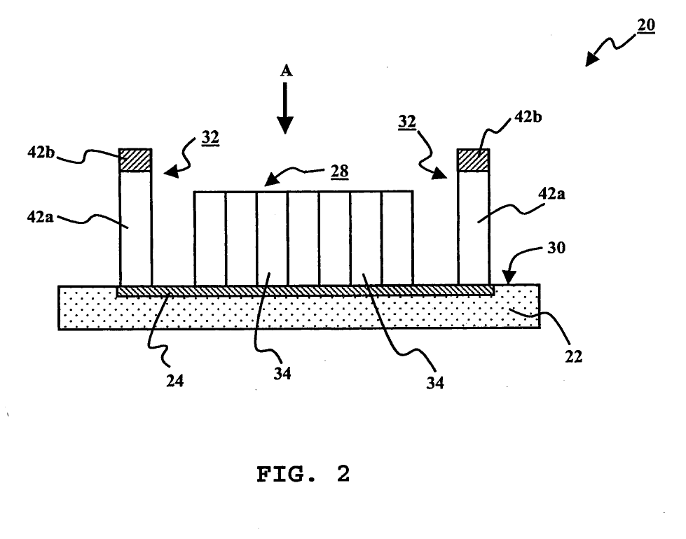

At least one of the first pillars 26 has a solder bump 40 formed at free-end 32 thereof. The solder bump 40 facilitates coupling of the corresponding first pillars 26 to the circuitry 38 via re-flow processes. Alternatively as shown in FIG. 2, at least one of the first pillars 26 has a base portion 42a formed from an electrically conductive material and a solder portion 42b formed from solder material. The solder portion 42b of each of the first pillars 32 terminates at the free-end 32.

Again, the solder portion 42a each of the first pillars 2634 is attached to the carrier 36 by re-flow processes. The first pillars 26 preferably have one of a rectangular or square shaped cross-section (not shown) but can alternatively assume other geometric shapes and elongated shapes.

The electrically conductive material of the base portion 42a of each of the first pillars 26 is preferably copper. In addition, the first pillars 26 can be further coated with one of oxide, chromium or nickel. The solder portion 42b of each of the first 26 pillars 34 preferably has a material composition of one of 63% tin and 37% lead, 99% tin and 1% silver, and 100% tin. Alternatively, the solder portion 42b of each of the first pillars 26 is preferably of tin and lead composition with a tin concentration of within a range of 60% to 70%.

Each adjacent pair of at least a portion of the second pillars 34 is inter-abutting. The second pillars 34 comprise a first connector pillar 44 and a second connector pillar 46. Each of the first connector pillar 44 and the second connector pillar 46 is electrically connected to the pattern 24 formed on the substrate 22.

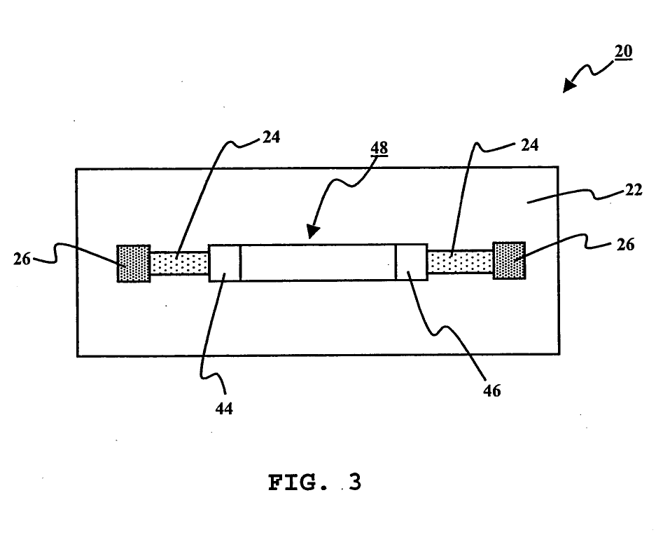

The second pillars 34 are arranged to form a wall 48 as shown in FIG. 3. The first connector pillar 44 and the second connector pillar 46 constitute two ends of the wall 48. The wall 48 is planarly shaped to form a resistor for providing resistance across the first connector pillar 44 and the second connector pillar 46.

Therefore, when the embedded passive component 20 is attached to the carrier 36, the passive structure 28 functions as a resistor, a passive element, to the circuitry 38 thereof.

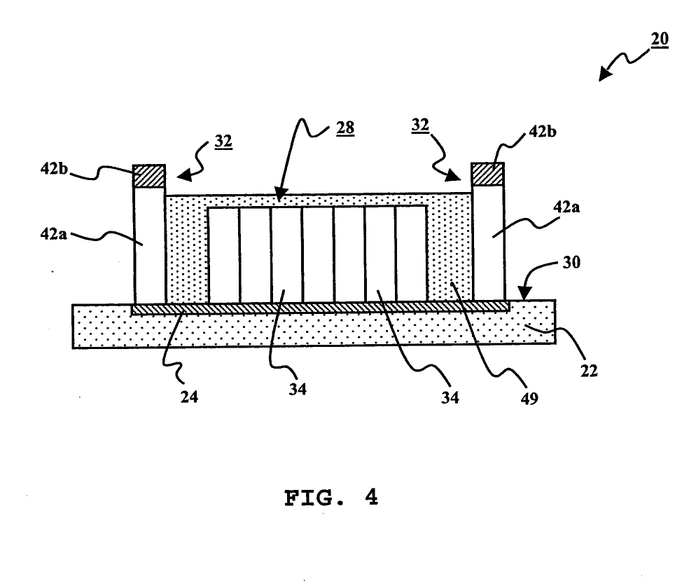

Additionally, an insulating layer 49 is preferably formed over the passive structure 28 for encapsulating the passive structure 28 as shown in FIG. 4.

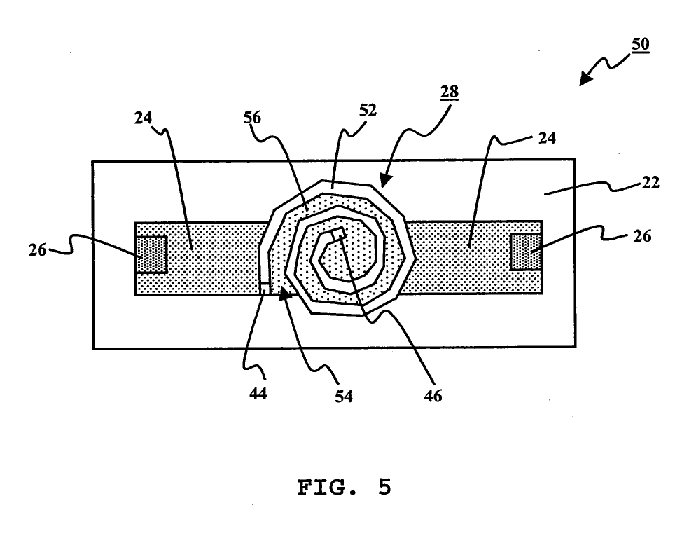

A second embodiment of the invention, an embedded passive component 50 as seen in FIG. 5 comprises three main elements: a substrate 22 with a pattern formed thereon 24, first pillars 26 and a passive structure 28 formed by second pillars 34. The descriptions in relation to the structural configurations of and positional relationships substrate 22, first pillars 26, the passive structure 28 and the carrier 36 with reference to FIG. 1 are incorporated herein.

In the second embodiment, the second pillars 34 are arranged to form a wall 52. The first connector pillar 44 and the second connector pillar 46 constitute two ends of the wall 52. The wall 52 is shaped as in inward spiral to form a duct 54 between two adjacent portions of the walls 52. Dielectric material 56 is deposited within the duct 54 to provide inductance across the first connector pillar 44 and the second connector pillar 46.

Therefore, when the embedded passive component 50 is attached to the carrier 36, the passive structure 28 functions as an inductor, a passive element, to the circuitry 38 thereof.

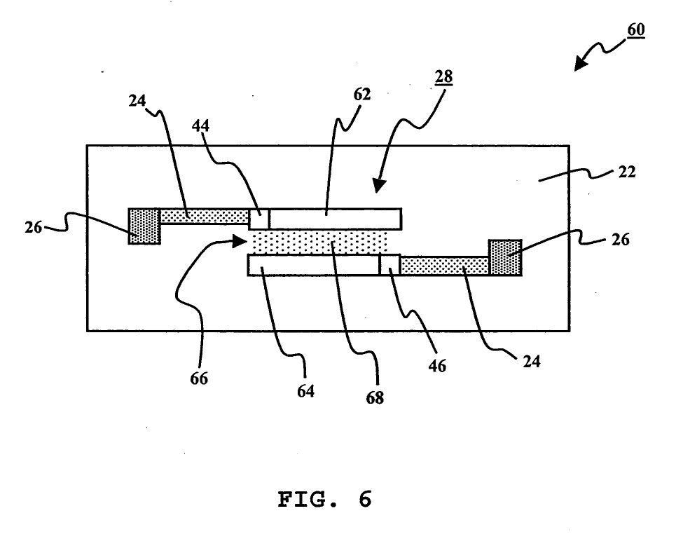

A third embodiment of the invention, an embedded passive component 60 as seen in FIG. 6 comprises three main elements: a substrate 22 with a pattern formed thereon 24, first pillars 26 and a passive structure 28 formed by second pillars 34. The descriptions in relation to the structural configurations of and positional relationships substrate 22, first pillars 26, the passive structure 28 and the carrier 36 with reference to FIG. 1 are incorporated herein.

In the third embodiment, the second pillars 34 is arranged to form a first wall 62 and a second wall 64. The first wall 62 is parallel to and spaced apart from the second wall 64 on the substrate 22. The first connector pillar 44 constitutes one end of the first wall 62 and the second connector pillar 46 constitutes one end of the second wall 64. Both the first wall 62 and the second wall 64 are planarly shaped and formed perpendicular to the substrate 22.

A duct 66 is formed between the first wall 62 and the second wall 64. Dielectric material 68 is deposited within the duct 66 to provide capacitance across the first connector pillar 44 and the second connector pillar 46.

Therefore, when the embedded passive component 60 is attached to the carrier 36, the passive structure 28 functions as a capacitor, a passive element, to the circuitry 38 thereof.

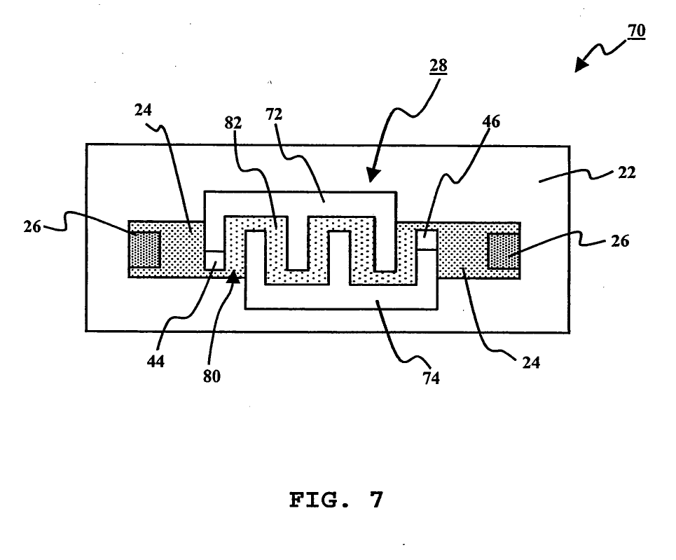

A fourth embodiment of the invention, an embedded passive component 70 as seen in FIG. 7 comprises three main elements: a substrate 22 with a pattern formed thereon 24, first pillars 26 and a passive structure 28 formed by second pillars 34. The descriptions in relation to the structural configurations of and positional relationships substrate 22, first pillars 26, the passive structure 28 and the carrier 36 with reference to FIG. 1 are incorporated herein.

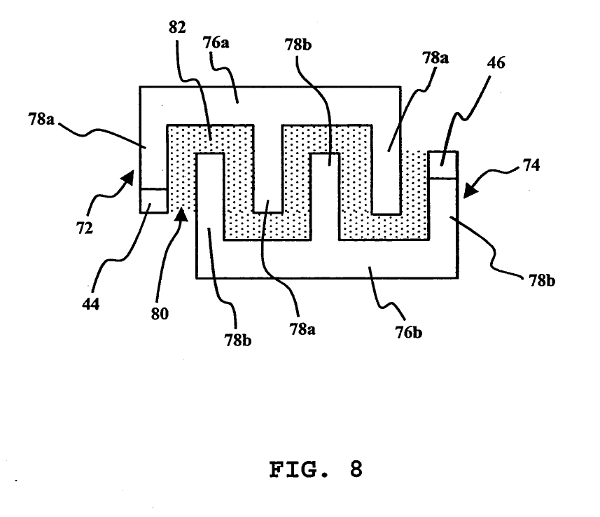

In the fourth embodiment, the second pillars 34 is arranged to form a first comb structure 72 and a second comb structure 74. The first comb structure 72 is spaced apart from the second comb structure 74 on the substrate 22. The first connector pillar 44 constitutes one portion of the first comb structure 72 and the second connector pillar 46 constitutes a portion of the second comb structure 74. As shown in FIG. 8, each of the first comb structure 72 and the second comb structure 74 comprises of a wall 76a/76b and a partitions 78a/78b extending from and spaced apart along the wall 76a/76b.

The partitions 78a/78b is substantially perpendicular to the wall 76a/76b and the substrate 22. The partitions 78a/78b and the wall 76a/76b of the first comb structure 72 and the second comb structure 74 are substantially planar. The partitions 78a of the first comb structure 72 interleaves the partitions 78b of the second comb structure 74 to form a duct 80 between adjacent portions thereof.

Dielectric material 82 is preferably deposited within the duct 80 to provide capacitance across the first connector pillar 44 and the second connector pillar 46. Therefore, when the embedded passive component 70 is attached to the carrier 36, the passive structure 28 functions as a capacitor, a passive element, to the circuitry 38 thereof.

The dielectric material 56/68/82 used in the corresponding second, third and fourth embodiments of the invention is preferably low-K dielectric material for reducing capacitance parasitics. Alternatively, the dielectric material 68/82 used in the third and fourth embodiments of the invention is high-K dielectric material for establishing a high capacitance capacitor.

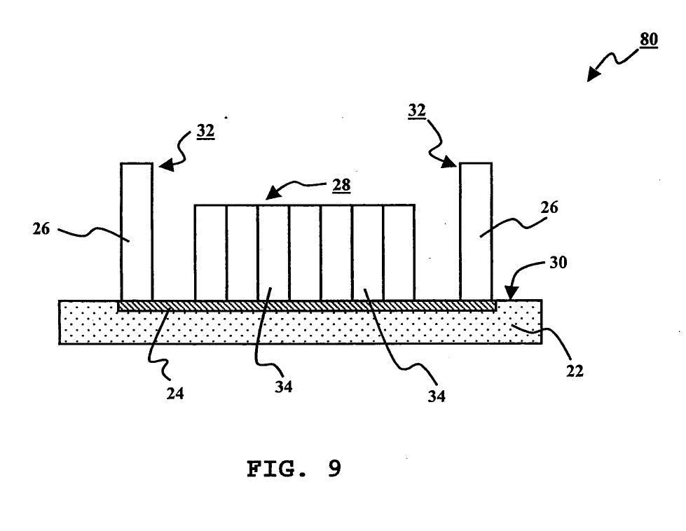

A fifth embodiment of the invention, an embedded passive component 80 as seen in FIG. 9 comprises three main elements: a substrate 22 with a pattern formed thereon 24, first pillars 26 and a passive structure 28 formed by second pillars 34. The descriptions in relation to the structural configurations of and positional relationships substrate 22, first pillars 26, the passive structure 28 and the carrier 36 with reference to FIG. 1 are incorporated herein.

In the fifth embodiment, each of the first pillars 26 is formed without a solder ball or the like solder-based feature thereon. Instead, each of the first pillars 26 extends from the mounting face 30 of the substrate 22 and terminates cleanly at the free end 32 thereof with the free end 32 being uncovered. The free end 32 of at least one of the first pillars 26 is subsequently coupleable to the circuitry 38 via conventional inter-connector bonding methods and processes.

In the foregoing manner, an embedded passive component is described according to five embodiments of the invention for addressing the foregoing disadvantages of passive components. Although only five embodiments of the invention are disclosed, it will be apparent to one skilled in the art in view of this disclosure that numerous changes and/or modification can be made without departing from the scope and spirit of the invention.

1. An embedded passive component comprising:
a substrate comprising a pattern formed thereon, the pattern being electrically conductive;
a first plurality of pillars extending from the substrate, each of the first plurality of pillars having a free end and at least one of the first plurality of pillars for coupling to a carrier having a circuitry; and
a passive structure for functioning as an electrically passive element, the passive structure comprising:
a second plurality of pillars extending from the substrate,
wherein the pattern on the substrate electrically communicates at least one of the first plurality of pillars with at least one of the second plurality of pillars,
whereby when at least one of the first plurality of pillars is coupled to the carrier, the at least one of the first plurality of pillars structurally inter-couples and spatially inter-displaces the substrate and the carrier to thereby electrically communicate the passive structure formed by the second plurality of pillars with the circuitry formed on the carrier.

2. The embedded passive component as in claim 1, the substrate being planar and, each of the first plurality of pillars and each of the second plurality of pillars being substantially perpendicular to the substrate.

3. The embedded passive component as in claim 1, each adjacent pair of at least a portion of the second plurality of pillars being inter-abutting.

4. The embedded passive component as in claim 1, at least one of the first plurality of pillars comprising a solder bump formed on the free-end thereof for coupling the at least one of the plurality of pillars to the circuitry on the carrier.

5. The embedded passive component as in claim 1, the second plurality of pillars having an arrangement for forming one of a resistor, an inductor and a capacitor.

6. The embedded passive component as in claim 5, the passive structure further comprising:
dielectric material integrated with the second plurality of pillars.

7. The embedded passive component as in claim 1, the second plurality of pillars comprising:
a first connector pillar; and
a second connector pillar, each of the first connector pillar and the second connector pillar extending from and being electrically connected to the pattern formed on the substrate.

8. The embedded passive component of claim 7, the second plurality of pillars being arranged to form a wall, the first connector pillar and the second connector pillar constituting two ends of the wall.

9. The embedded passive structure of claim 8, the passive structure being a resistor when the wall formed by the second plurality of pillars is substantially planar.

10. The embedded passive component as in claim 8, the passive structure further comprising:
a duct formed between two adjacent portion of the wall formed by the second plurality of pillars when arranged in an inward spiral; and
dielectric material being deposited in the duct,
wherein the passive structure is an inductor across the first connector pillar and the second connector pillar.

11. The embedded passive component of claim 7, the second plurality of pillars being arranged to form a first wall and a second wall being adjacent to and spaced apart from the first wall, the first connector pillar constituting one end of the first wall and the second connector pillar constituting one end of the second wall.

12. The embedded passive component as in claim 11, the passive structure further comprising:
a duct formed between the first wall and the second wall; and
dielectric material being deposited within the duct,
wherein the passive structure is a capacitor across the first connector pillar and the second connector pillar.

13. The embedded passive component as in claim 12, each of the first wall and the second wall being planarly shaped.

14. The embedded passive component of claim 7, the second plurality of pillars being arranged to form a first comb structure and a second comb structure, the first connector pillar constituting a portion of the first comb structure and the second connector pillar constituting a portion of the second comb structure.

15. The embedded passive component as in claim 14, the first comb structure and the second comb structure being spaced apart and the passive structure further comprising:
dielectric material being deposited between the first comb structure and the second comb structure,
wherein the passive structure is a capacitor across the first connector pillar and the second connector pillar.

16. The embedded passive component as in claim 14, each of the first comb structure and the second comb structure comprising:
a wall formed substantially perpendicular to the substrate; and
a plurality of partitions formed substantially perpendicular to the wall and the substrate.

17. The embedded passive component as in claim 16, the passive structure further comprising:
a duct formed between the first comb structure and the second comb structure when the plurality of partitions of each thereof are interleaved; and
dielectric material being deposited within the duct,
wherein the passive structure is a capacitor across the first connector pillar and the second connector pillar.

18. The embedded passive component as in claim 17, the wall and the plurality of partitions of each of the first comb structure and the second comb structure are planarly shaped.

19. The embedded passive component as in claim 1, further comprising:
an insulating layer formed over at least a portion of the substrate for encapsulating the second plurality of pillars therein.

20. The embedded passive component as in claim 1, at least one of the first plurality of pillars being formed from at least two conductive materials.

21. The embedded passive component as in claim 20, one of the at least two conductive material being solder material.

22. An embedded passive component comprising:
a substrate comprising a pattern formed thereon, the pattern being electrically conductive and the substrate being planar;
a first plurality of pillars extending from the substrate, each of the first plurality of pillars having a free end and at least one of the first plurality of pillars for coupling to a carrier having a circuitry, each of the first plurality of pillars being substantially perpendicular to the substrate; and
a passive structure for functioning as an electrically passive element, the passive structure comprising:
a second plurality of pillars extending from the substrate, each of the second plurality of pillars being substantially perpendicular to the substrate, each adjacent pair of a portion of the second plurality of pillars being inter-abutting,
wherein the pattern on the substrate electrically communicates at least one of the first plurality of pillars with at least one of the second plurality of pillars,
whereby when at least one of the first plurality of pillars is coupled to the carrier, the at least one of the first plurality of pillars structurally inter-couples and spatially inter-displaces the substrate and the carrier to thereby electrically communicate the passive structure formed by the second plurality of pillars with the circuitry formed on the carrier.

23. The embedded passive component as in claim 22, the second plurality of pillars having an arrangement for forming one of a resistor, an inductor and a capacitor.

24. The embedded passive component as in claim 23, the passive structure further comprising:
dielectric material integrated with the second plurality of pillars.

25. An embedded passive component comprising:
a substrate comprising a pattern formed thereon, the pattern being electrically conductive and the substrate being planar; and
a passive structure for functioning as an electrically passive element, the passive structure comprising:
a plurality of pillars extending from the substrate, each of the plurality of pillars being substantially perpendicular to the substrate, each adjacent pair of a portion of the second plurality of pillars being inter-abutting,
wherein when the pattern is electrically connected to a circuitry, the pattern on the substrate electrically communicates at least one of the plurality of pillars with the circuitry.

26. The embedded passive component as in claim 25, the plurality of pillars having an arrangement for forming one of a resistor, an inductor and a capacitor.

27. The embedded passive component as in claim 26, the passive structure further comprising:
dielectric material integrated with the plurality of pillars.

28. The embedded passive component as in claim 25, the plurality of pillars comprising:
a first connector pillar; and
a second connector pillar, each of the first connector pillar and the second connector pillar extending from and being electrically connected to the pattern formed on the substrate.

29. The embedded passive component of claim 28, the plurality of pillars being arranged to form a wall, the first connector pillar and the second connector pillar constituting two ends of the wall,
wherein the passive structure being a resistor when the wall formed by the plurality of pillars is substantially planar.

30. The embedded passive component as in claim 28, the passive structure further comprising:
a duct formed between two adjacent portion of the wall formed by the plurality of pillars when arranged in an inward spiral; and
dielectric material being deposited in the duct,
wherein the passive structure is an inductor across the first connector pillar and the second connector pillar.

31. The embedded passive component of claim 28, the plurality of pillars being arranged to form a first wall and a second wall being adjacent to and spaced apart from the first wall, the first connector pillar constituting one end of the first wall and the second connector pillar constituting one end of the second wall.

32. The embedded passive component as in claim 31, the passive structure further comprising:
a duct formed between the first wall and the second wall; and
dielectric material being deposited within the duct,
wherein each of the first wall and the second wall being planarly shaped, and the passive structure is a capacitor across the first connector pillar and the second connector pillar.

33. The embedded passive component of claim 28, the plurality of pillars being arranged to form a first comb structure and a second comb structure, the first connector pillar constituting a portion of the first comb structure and the second connector pillar constituting a portion of the second comb structure.

34. The embedded passive component as in claim 33, the first comb structure and the second comb structure being spaced apart and the passive structure further comprising:
dielectric material being deposited between the first comb structure and the second comb structure,
wherein the passive structure is a capacitor across the first connector pillar and the second connector pillar.

35. The embedded passive component as in claim 33, each of the first comb structure and the second comb structure comprising:
a wall formed substantially perpendicular to the substrate;
a plurality of partitions formed substantially perpendicular to the wall and the substrate;
a duct formed between the first comb structure and the second comb structure when the plurality of partitions of each thereof are interleaved; and
dielectric material being deposited within the duct,
wherein the wall and the plurality of partitions of each of the first comb structure and the second comb structure are planarly shaped, and the passive structure is a capacitor across the first connector pillar and the second connector pillar.

36. The embedded passive component as in claim 25, further comprising:
an insulating layer formed over at least a portion of the substrate for encapsulating the plurality of pillars therein.
